(19) United States
(12) Patent Application Publication
(10) Pub. No.: US 2021/0197236 A1
(43) Pub. Date: Jul. 1, 2021

(54) AIR CURTAIN APPARATUS AND AN AIRFLOW ACCELERATOR FOR AN AIR CURTAIN APPARATUS

(71) Applicant: Temple Technology Ltd., Hsinchu County (TW)

(72) Inventors: Wang Ming, Hsinchu County (TW); HsiangTsung Yeh Wang, Hsinchu County (TW)

(21) Appl. No.: 17/033,992

(22) Filed: Sep. 28, 2020

(30) Foreign Application Priority Data
Dec. 25, 2019 (TW) 108217182
Dec. 25, 2019 (TW) 108217183

(51) Int. Cl. B08B 3/02; H01L 21/67; H01L 21/02

(52) U.S. Cl. CPC B08B 3/022; B08B 2205/00; H01L 21/02087; H01L 21/67017

(57) ABSTRACT

This invention provides an air curtain apparatus, which are characterized by making the dry and clean airflow and/or de-electrostatic ionized airflow sprayed by the air-spraying heads or air-spraying slit thereof be further accelerated by a funnel structure and flowed vertically toward to a predetermined target, thereby less dry and clean airflow and/or a de-electrostatic ionized airflow are needed to achieve an idea dry and clean and/or de-electrostatic state, and the cost for cleaning or removing static electricity can be highly reduced.

This application claims the benefit of Taiwanese application serial No.108217182, filed on Dec. 25, 2019, and the benefit of Taiwanese application serial No.108217183, filed on Dec. 25, 2019, the subject matter of which is incorporated herein by reference.

### BACKGROUND OF THE INVENTION

### Field of the Invention

The invention relates in general to an air curtain apparatus and an airflow accelerator for an air curtain apparatus, and particularly relates to an air curtain apparatus for a semiconductor cleaning apparatus and an airflow accelerator for an air curtain apparatus for a semiconductor cleaning apparatus, and more especially relates to an air curtain apparatus and an airflow accelerator for an air curtain apparatus for a gate valve or an opening between the wafer cassette and the processing environment.

### Description of the Related Art

During a series of semiconductor processes, a highly clean environment is necessary to ensure the wafers will not be damaged by the particles in the air, moisture, other chemical contaminates and static electricity and ensure the yield rate thereof. However, it costs a lot to provide a clean, dry and/or de-electrostatic environment during a series of semiconductor processes. Therefore, an air curtain apparatus is usually introduced to reduce the cost.

FIGS. 1 and 2 ate cross-sectional view and side view of a conventional air curtain apparatus 100 for using in the semiconductor process. As shown in FIG. 1, a conventional air curtain apparatus 100 is illustrated, which comprises an article 10, an air inlet 12, and a plurality of air-spraying heads 15 formed on a side of the article 10 facing a target, wherein the dry and clean airflow and/or the de-electrostatic ionized airflow is inputted to the conventional air curtain apparatus 100 through the air inlet 12, and then sprayed the dry and clean airflow and/or the de-electrostatic ionized airflow toward the target through the air-spraying heads 15 to provide a dry, clean and/or de-electrostatic environment for semiconductor process. As shown in FIG. 2, another the conventional air curtain apparatus 200 is illustrated, which comprises an article 20, an air inlet 12, and an air-spraying slit 24 formed on a side of the article 20 facing a target, wherein the dry and clean airflow and/or the de-electrostatic ionized airflow is inputted to the conventional air curtain apparatus 200 through the air inlet 22, and then sprayed the dry and clean airflow and/or the de-electrostatic ionized airflow toward the target through the air-spraying slit 24 to provide a dry, clean and/or de-electrostatic environment for semiconductor process.

However, the dry and clean airflow and/or the de-electrostatic ionized airflow toward the target through the air-spraying heads 15 of the conventional air curtain apparatus 100 or through the air-spraying slit 24 of the conventional air curtain apparatus 200 is not 100% substantially vertically toward to the target, therefore part of the dry and clean airflow and/or the de-electrostatic ionized airflow will be interference by adjacent dry and clean airflow and/or the de-electrostatic ionized airflow and result in ineffective airflow or de-electrostatic ionized airflow, thereby more dry and clean airflow and/or the de-electrostatic ionized airflow is needed to achieve an idea dry, clean and/or de-electrostatic environment for semiconductor process and results in higher cost.

Accordingly, an air curtain apparatus and an airflow accelerator for an air curtain apparatus for providing a clean, dry and de-electrostatic environment during semiconductor process with lower cost is highly expected by the semiconductor industry.

### SUMMARY OF THE INVENTION

An aspect of this invention is to provide an air curtain apparatus for spraying a dry and clean airflow and/or a de-electrostatic ionized airflow toward a target, comprising: an article with a first surface, a second surface, a third surface and a fourth surface adjacent to each other, and a first side surface and a second side surface on opposite end terminals of the article, wherein the first surface faces to the target, the first surface faces to the third surface, the second surface faces to the fourth surface, and the first side surface is adjacent to edges of the first surface, the second surface, the third surface and the fourth surface, and the second side surface is adjacent to another edges of the first surface, the second surface, the third surface and the fourth surface; an air inlet, formed on the first side surface or the second side surface of the article; a plurality of air-spraying heads formed on the first surface of the article; and an accelerator, comprising: a first conductive thin film, floatingly formed on the second surface adjacent to the first surface, wherein a first distance d1 that the first conductive thin film protruding out of the first surface is greater than a second distance d2 that the air-spraying heads protruding out of the first surface; and a second conductive thin film, floatingly formed on the fourth surface adjacent to the first surface, wherein a first distance d1 that the second conductive thin film protruding out of the first surface is greater than a second distance d2 that the air-spraying heads protruding out of the first surface; wherein, the first conductive thin film and the second conductive thin film protruding out of the first surface form a funnel structure owing to the gravity, which contributes to the dry and clean airflow and/or the de-electrostatic ionized airflow sprayed by the air-spraying heads be accelerated by the funnel structure and flowed vertically toward to the target.

The air curtain apparatus as mentioned above, wherein the first conductive thin film and the second conductive thin film are flexible conductive plastic thin films or flexible metallic thin films.

Another aspect of this invention is to provide another air curtain apparatus for spraying a dry and clean airflow and/or a de-electrostatic ionized airflow toward a target, comprising: an article with a first surface, a second surface, a third surface and a fourth surface adjacent to each other, and a first side surface and a second side surface on opposite end terminals of the article, wherein the first surface faces to the target, the first surface faces to the third surface, the second surface faces to the fourth surface, and the first side surface is adjacent to edges of the first surface, the second surface, the third surface and the fourth surface, and the second side surface is adjacent to another edges of the first surface, the second surface, the third surface and the fourth surface; an air inlet, formed on the first side surface or the second side surface of the article; an air-spraying slit formed on the first surface of the article; and an accelerator, comprising: a first conductive thin film, floatingly formed on the second surface adjacent to the first surface, wherein a first distance d1 that the first conductive thin film protruding out of the first surface is greater than a second distance d2 that the air-spraying slit protruding out of the first surface; and a second conductive thin film, floatingly formed on the fourth surface adjacent to the first surface, wherein a first distance d1 that the second conductive thin film protruding out of the first surface is greater than a second distance d2 that the air-spraying slit protruding out of the first surface; wherein, the first conductive thin film and the second conductive thin film protruding out of the first surface form a funnel structure owing to the gravity, which contributes to the dry and clean airflow and/or the de-electrostatic ionized airflow sprayed by the air-spraying slit be accelerated by the funnel structure and flowed vertically toward to the target.

The another air curtain as mentioned above, wherein the first conductive thin film and the second conductive thin film are flexible conductive plastic thin films or flexible metallic thin films.

The another air curtain as mentioned above, wherein the flexible conductive plastic thin films are made of polyimide.

The another air curtain as mentioned above, wherein the flexible metallic thin films are made of aluminum foil, tin foil or copper foil.

Another aspect of this invention is to provide an airflow accelerator for an air curtain apparatus, comprising: a base part, upwardly extending along with a first direction D1; a terminal part; and a connecting part for connecting the base part and the terminal part, extending along with a second direction D2, and an acute angle a is formed between the first direction D1 and the second direction D2; wherein when the airflow accelerator for an air curtain apparatus is placed adjacent to a semiconductor equipment or a semiconductor processing room, a first gap g1 between the terminal part of the airflow accelerator for an air curtain apparatus and the semiconductor equipment or the semiconductor processing room is greater than a second gap g2 between the base part of the airflow accelerator for an air curtain apparatus and the semiconductor equipment or the semiconductor processing room, and an airflow with a first velocity of V1 sprayed by the air curtain apparatus will be accelerated by the airflow accelerator to generate an airflow with a second velocity of V2 when passing from the first gap g1 between the terminal part of the airflow accelerator for an air curtain apparatus and the semiconductor equipment or the semiconductor processing room 50 through the second gap g2 between the terminal part of the airflow accelerator for an air curtain apparatus and the semiconductor equipment or the semiconductor processing room.

The airflow accelerator for an air curtain apparatus as mentioned above, wherein the airflow accelerator is made of a conductive plastic material or a metallic material.

The airflow accelerator for an air curtain apparatus as mentioned above, wherein the conductive plastic material is polyimide.

The airflow accelerator for an air curtain apparatus as mentioned above, wherein the metallic material is aluminum, tin or copper.

The airflow accelerator for an air curtain apparatus as mentioned above, further comprises a first side part adjacent to the base part, the connecting part and the terminal part.

The airflow accelerator for an air curtain apparatus as mentioned above, further comprises a second side part adjacent to the base part, the connecting part and the terminal part, wherein the first side part and the second side part are opposite to each other.

The above and other aspects of the invention will become better understood with regard to the following detailed description of the preferred but non-limiting embodiment(s). These and other aspects of the invention will become apparent from the following description of the presently preferred embodiments. The detailed description is merely illustrative of the invention and does not limit the scope of the invention, which is defined by the appended claims and equivalents thereof. As would be obvious to one skilled in the art, many variations and modifications of the invention may be affected without departing from the spirit and scope of the novel concepts of the disclosure.

### BRIEF DESCRIPTION OF THE DRAWINGS

FIG. 1 is a cross-sectional view of a conventional air curtain apparatus 100 for using in the semiconductor process.

FIG. 2 is a cross-sectional view of another conventional air curtain apparatus 200 for using in the semiconductor process.

FIG. 3A is a cross-sectional view showing an air curtain apparatus 300 for using in the semiconductor process of Embodiment 1 according to this present invention.

FIG. 3B is a side view showing the air curtain apparatus 300 for using in the semiconductor process of Embodiment 1 according to this present invention.

FIG. 4A is a cross-sectional view showing another air curtain apparatus 400 for using in the semiconductor process of Embodiment 2 according to this present invention.

FIG. 4B is a side view showing the air curtain apparatus 400 for using in the semiconductor process of Embodiment 2 according to this present invention.

FIG. 5A is a perspective view showing an airflow accelerator 40 for an air curtain apparatus of Embodiment 3 according to this invention.

FIG. 5B is a cross-sectional view showing an airflow accelerator 40 for an air curtain apparatus of Embodiment 3 according to this invention.

FIG. 6 is a schematic side view showing a conventional air curtain apparatus 100 for using in the semiconductor process equipped with the airflow accelerator 40 for an air curtain apparatus as shown in FIG. 5.

FIG. 7 is a schematic side view showing a conventional air curtain apparatus 200 for using in the semiconductor process equipped with the airflow accelerator 40 for an air curtain apparatus as shown in FIG. 5.

FIG. 8 is a perspective view showing another airflow accelerator 40′ for an air curtain apparatus of another embodiment according to this invention.

FIG. 9 is a perspective view showing another airflow accelerator 40″ for an air curtain apparatus of another embodiment according to this invention.

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

In the following description, numerous specific details are described in detail in order to enable the reader to fully understand the following examples. However, embodiments of the present invention may be practiced in case no such specific details. In other cases, in order to simplify the drawings the structure of the apparatus known only schematically depicted in figures.

### EMBODIMENT

### Embodiment 1

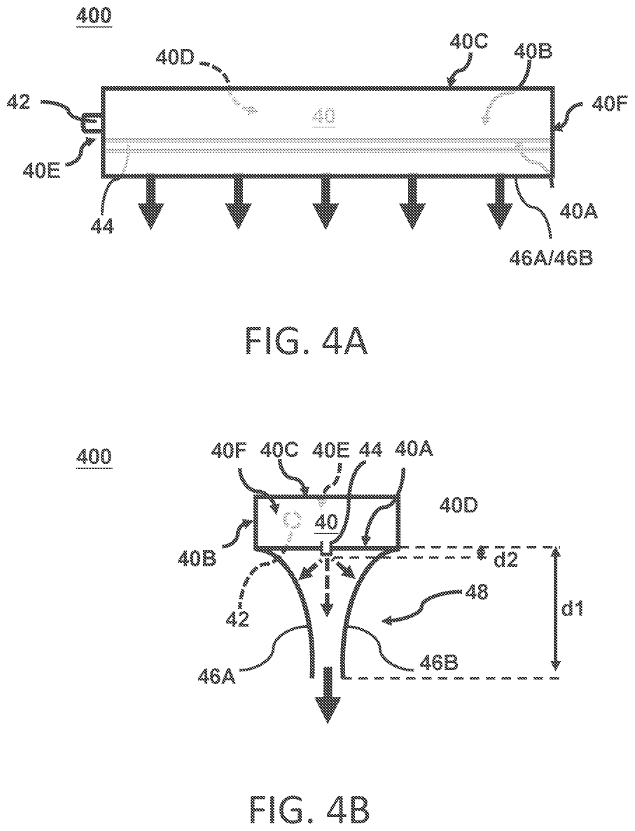

Please refer to FIGS. 3A˜3B, which are cross-sectional view and side view showing an air curtain apparatus 300 for using in the semiconductor process of Embodiment 1 according to this present invention.

As showing in FIGS. 3A˜3B, the air curtain apparatus 300 for spraying a dry and clean airflow and/or a de-electrostatic ionized airflow toward a target (not shown) comprises: an article 30 with a first surface 30A, a second surface 30B, a third surface 30C and a fourth surface 30D adjacent to each other, and a first side surface 30E and a second side surface 30F on opposite end terminals (not labeled) of the article 30, wherein the first surface 30A faces to the target, the first surface 30A faces to the third surface 30C, the second surface 30B faces to the fourth surface 30D, and the first side surface 30E is adjacent to edges of the first surface 30A, the second surface 30B, the third surface 30C and the fourth surface 30D, and the second side surface 30F is adjacent to another edges of the first surface 30A, the second surface 30B, the third surface 30C and the fourth surface 30D; an air inlet 32 formed on the first side surface 30E of the article 30; a plurality of air-spraying heads 35 formed on the first surface 30A of the article 30; and an accelerator 38, comprising: a first conductive thin film 36A floatingly formed on the second surface 30B adjacent to the first surface 30A, wherein a first distance d1 that the first conductive thin 36A film protruding out of the first surface 30A is greater than a second distance d2 that the air-spraying heads 35 protruding out of the first surface 30A; and a second conductive thin film 36B floatingly formed on the fourth surface 30D adjacent to the first surface 30A, wherein a first distance d1 that the second conductive thin film 36B protruding out of the first surface 30A is greater than a second distance d2 that the air-spraying heads 35 protruding out of the first surface 30A; wherein, the first conductive thin film 36A and the second conductive thin film 36B protruding out of the first surface 30A form a funnel structure (not labeled) owing to the gravity, which contributes to the dry and clean airflow and/or the de-electrostatic ionized airflow sprayed by the air-spraying heads 35 be accelerated by the funnel structure (no labeled) and flowed vertically toward to the target (not shown).

The air curtain apparatus 300 as mentioned above, wherein the first conductive thin film 36A and the second conductive thin film 36B are flexible conductive plastic thin films for example but not limited to polyimide thin film or flexible metallic thin films for example but not limited to aluminum foil, tin foil or copper foil. According to other embodiments of this invention, other flexible conductive plastic thin films or other flexible metallic thin films are also applicable.

Comparing to the conventional air curtain apparatus, the dry and clean airflow and/or de-electrostatic ionized airflow sprayed by the air-spraying heads 35 can be further accelerated by the funnel structure (no labeled) and flowed vertically toward to the target (not shown), thereby less dry and clean airflow and/or a de-electrostatic ionized airflow are needed by the air curtain apparatus 300 of the embodiment 2 of this invention to achieve an idea dry and clean and/or de-electrostatic state, and the cost for cleaning or removing static electricity can be highly reduced.

### Embodiment 2

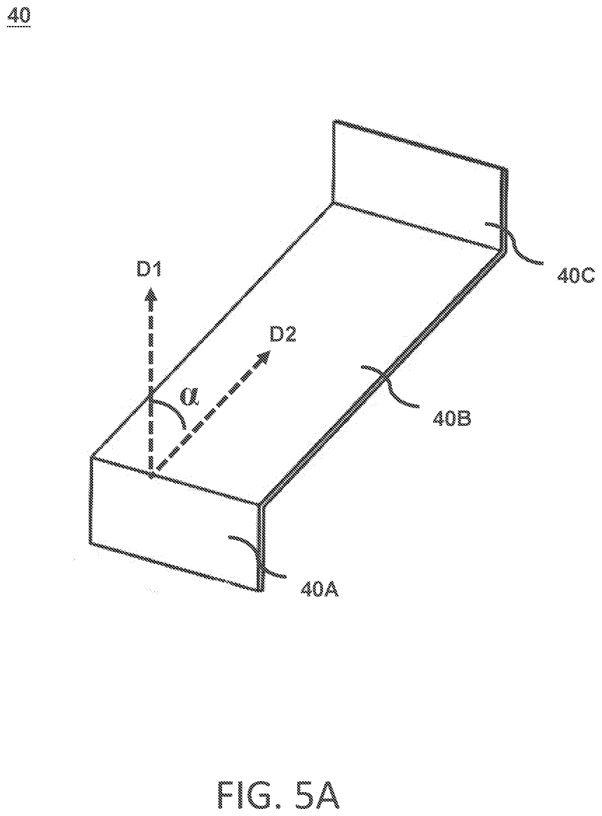

Please refer to FIGS. 4A˜4B, which are cross-sectional view and side view showing an air curtain apparatus 400 for using in the semiconductor process of Embodiment 2 according to this present invention.

As showing in FIGS. 4A˜4B, the air curtain apparatus 400 for spraying a dry and clean airflow and/or a de-electrostatic ionized airflow toward a target (not shown) comprises: an article 40 with a first surface 40A, a second surface 40B, a third surface 40C and a fourth surface 40D adjacent to each other, and a first side surface 40E and a second side surface 40F on opposite end terminals (not labeled) of the article 40, wherein the first surface 40A faces to the target, the first surface 40A faces to the third surface 40C, the second surface 40B faces to the fourth surface 40D, and the first side surface 40E is adjacent to edges of the first surface 40A, the second surface 40B, the third surface 40C and the fourth surface 40D, and the second side surface 40F is adjacent to another edges of the first surface 40A, the second surface 40B, the third surface 30C and the fourth surface 40D; an air inlet 42 formed on the first side surface 40E of the article 40; an air-spraying slit 44 formed on the first surface 40A of the article 40; and an accelerator 48, comprising: a first conductive thin film 46A floatingly formed on the second surface 40B adjacent to the first surface 40A, wherein a first distance d1′ that the first conductive thin 46A film protruding out of the first surface 40A is greater than a second distance d2′ that the air-spraying slit 44 protruding out of the first surface 40A; and a second conductive thin film 46B floatingly formed on the fourth surface 40D adjacent to the first surface 40A, wherein a first distance d1 that the second conductive thin film 46B protruding out of the first surface 340A is greater than a second distance d2 that the air-spraying slit 44 protruding out of the first surface 40A; wherein, the first conductive thin film 46A and the second conductive thin film 46B protruding out of the first surface 40A form a funnel structure (not labeled) owing to the gravity, which contributes to the dry and clean airflow and/or the de-electrostatic ionized airflow sprayed by the air-spraying slit 44 be accelerated by the funnel structure (no labeled) and flowed vertically toward to the target (not shown).

The air curtain apparatus 400 as mentioned above, wherein the first conductive thin film 46A and the second conductive thin film 46B are flexible conductive plastic thin films for example but not limited to polyimide thin film or flexible metallic thin films for example but not limited to aluminum foil, tin foil or copper foil. According to other embodiments of this invention, other flexible conductive plastic thin films or other flexible metallic thin films are also applicable.

Comparing to the conventional air curtain apparatus, the dry and clean airflow and/or de-electrostatic ionized airflow sprayed by the air-spraying slit 44 can be further accelerated by the funnel structure (no labeled) and flowed vertically toward to the target (not shown), thereby less dry and clean airflow and/or a de-electrostatic ionized airflow are needed by the air curtain apparatus 400 of the embodiment 2 of this invention to achieve an idea dry and clean and/or de-electrostatic state, and the cost for cleaning or removing static electricity can be highly reduced.

### Embodiment 3

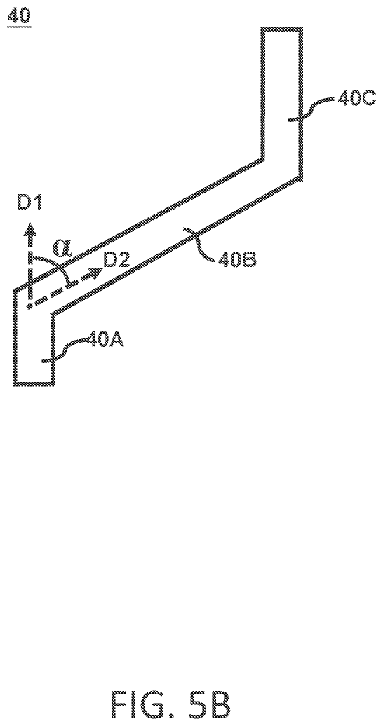

Please refer to FIGS. 5A˜5B. FIG. 5A is a perspective view showing an airflow accelerator 40 for an air curtain apparatus of Embodiment 3 according to this invention. FIG. 5B is a cross-sectional view showing an airflow accelerator 40 for an air curtain apparatus of Embodiment 3 according to this invention.

As shown in FIGS. 5A˜5B, an airflow accelerator 40 for an air curtain apparatus is illustrated, which comprises: a base part 40A upwardly extending along with a first direction D1; a terminal part 40C; and a connecting part 40B for connecting the base part 40A and the terminal part 40C extending along with a second direction D2, and an acute angle a is formed between the first direction D1 and the second direction D2. The airflow accelerator 40 for an air curtain apparatus can be made of a conductive plastic material for example but not limited to polyimide or a metallic material for example but not limited to aluminum, tin or copper.

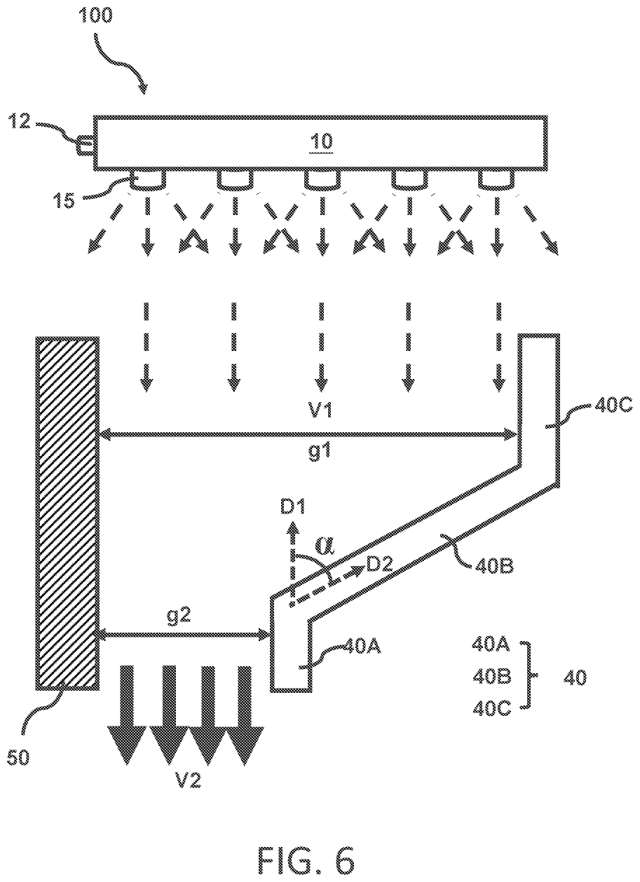

As shown in FIG. 6, when a conventional air curtain apparatus 100 for using in the semiconductor process equipped with the airflow accelerator 40 for an air curtain apparatus as shown in FIG. 5, and the airflow accelerator 40 for an air curtain apparatus is placed adjacent to a semiconductor equipment or a semiconductor processing room 50, a first gap g1 between the terminal part 40C of the airflow accelerator 40 for an air curtain apparatus and the semiconductor equipment or the semiconductor processing room 50 is greater than a second gap g2 between the base part 40A of the airflow accelerator 40 for an air curtain apparatus and the semiconductor equipment or the semiconductor processing room 50, and the airflow with a first velocity of V1 sprayed by the air curtain apparatus 100 will be accelerated by the airflow accelerator 40 to generate an airflow with a second velocity of V2 when passing from the first gap g1 between the terminal part 40C of the airflow accelerator 40 for an air curtain apparatus and the semiconductor equipment or the semiconductor processing room 50 through the second gap g2 between the terminal part 40C of the airflow accelerator 40 for an air curtain apparatus and the semiconductor equipment or the semiconductor processing room 50.

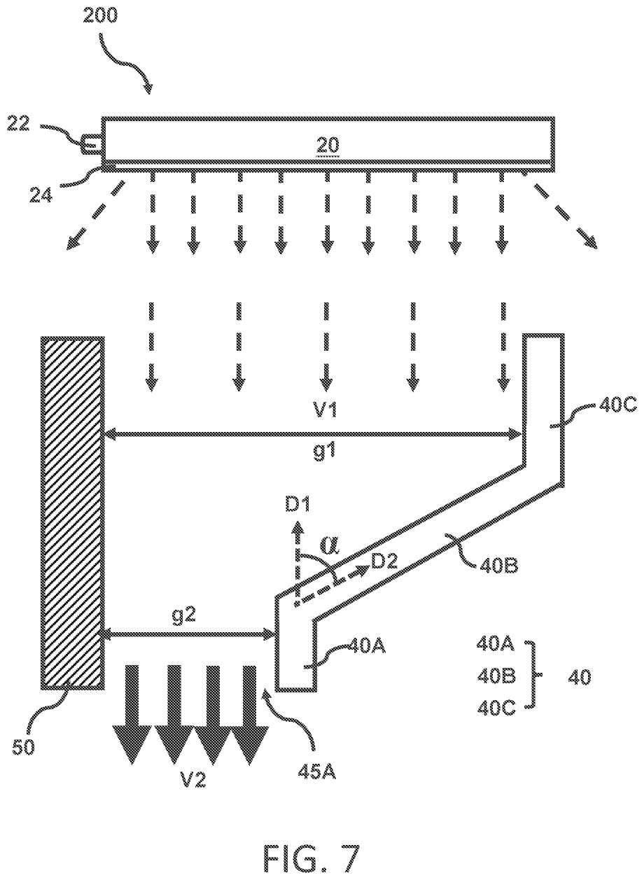

As shown in FIG. 7, when a conventional air curtain apparatus 200 for using in the semiconductor process equipped with the airflow accelerator 40 for an air curtain apparatus as shown in FIG. 5, and the airflow accelerator 40 for an air curtain apparatus is placed adjacent to a semiconductor equipment or a semiconductor processing room 50, a first gap g1 between the terminal part 40C of the airflow accelerator 40 for an air curtain apparatus and the semiconductor equipment or the semiconductor processing room 50 is greater than a second gap g2 between the base part 40A of the airflow accelerator 40 for an air curtain apparatus and the semiconductor equipment or the semiconductor processing room 50, and the airflow with a first velocity of V1 sprayed by the air curtain apparatus 100 will be accelerated by the airflow accelerator 40 to generate an airflow with a second velocity of V2 when passing from the first gap g1 between the terminal part 40C of the airflow accelerator 40 for an air curtain apparatus and the semiconductor equipment or the semiconductor processing room 50 through the second gap g2 between the terminal part 40C of the airflow accelerator 40 for an air curtain apparatus and the semiconductor equipment or the semiconductor processing room 50.

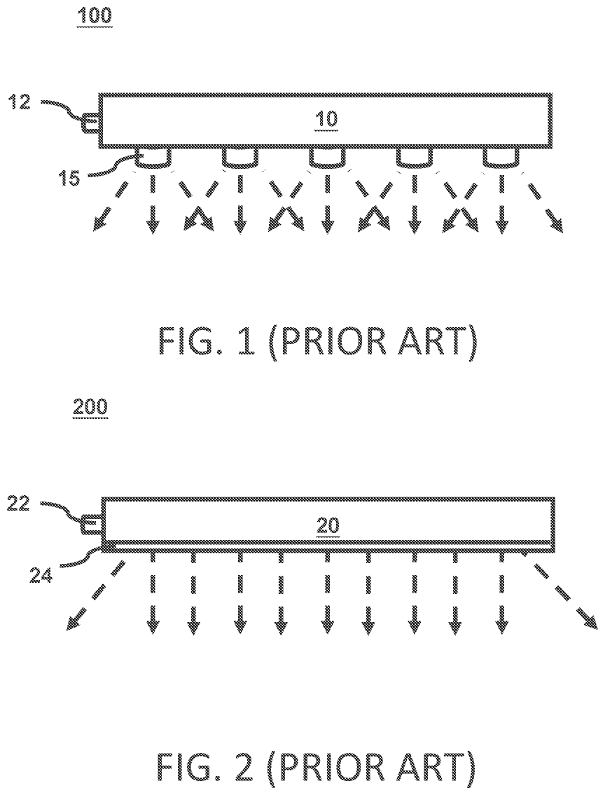

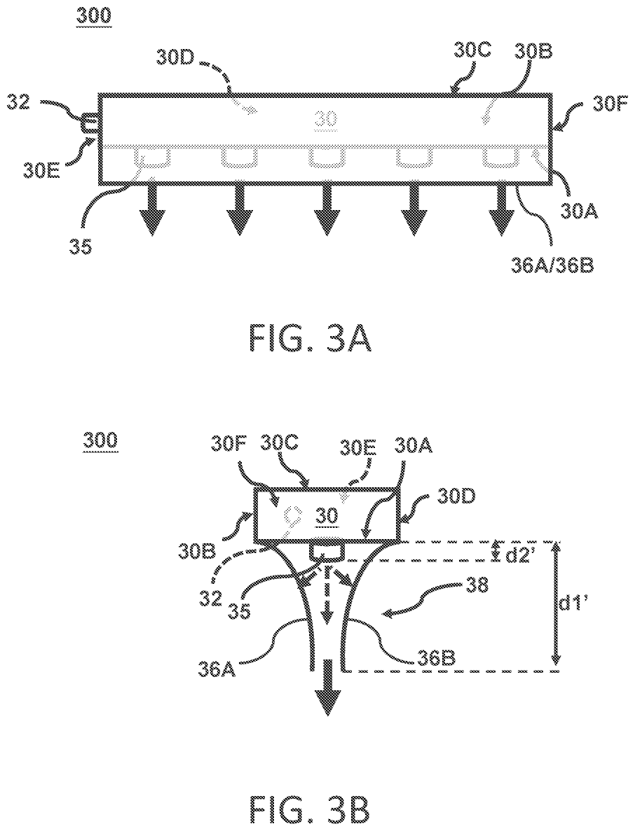

Comparing to the conventional air curtain apparatus 100 shown in FIG. 1 and the conventional air curtain apparatus 200 shown in FIG. 2, the dry and clean airflow and/or de-electrostatic ionized airflow sprayed by the conventional air curtain apparatus 100 or 200 can be further accelerated by the airflow accelerator 40 of the Embodiment 3 of this invention and flowed vertically toward to the target (not shown), thereby less dry and clean airflow and/or a de-electrostatic ionized airflow are needed by the conventional air curtain apparatus 100 or 200 to achieve an idea dry and clean and/or de-electrostatic state, and the cost for cleaning or removing static electricity can be highly reduced.

Moreover, the airflow accelerator 40 for an air curtain apparatus as shown in FIGS. 5A˜5B can also be used to accelerate the dry and clean airflow and/or de-electrostatic ionized airflow sprayed by the air curtain apparatus 300 shown in FIGS. 3A˜3B or the air curtain apparatus 400 shown in FIGS. 4A˜4B according to this present invention.

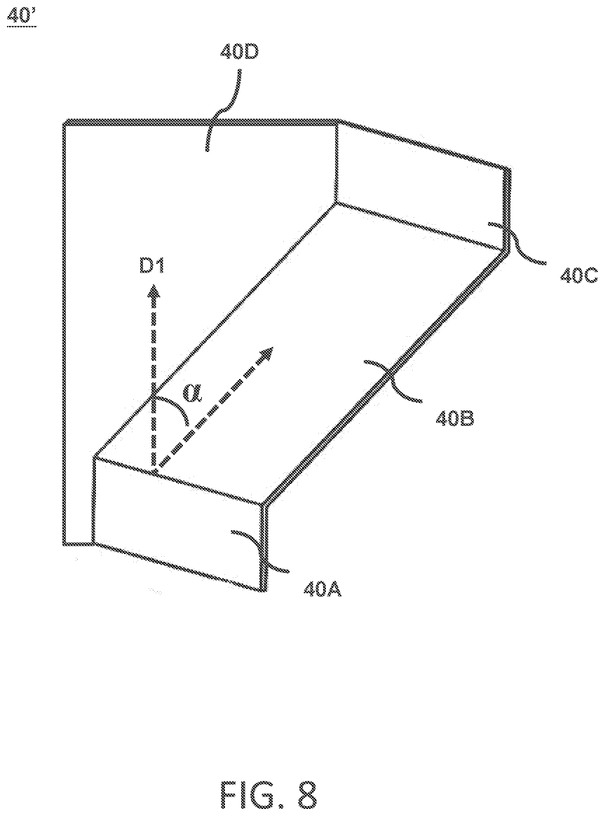

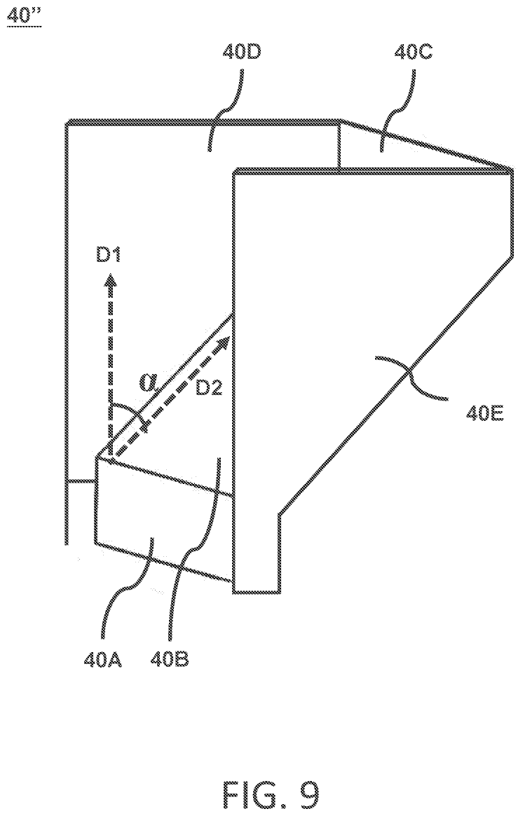

Furthermore, another airflow accelerator 40′ for an air curtain apparatus as shown in FIG. 8 and another airflow accelerator 40″ for an air curtain apparatus as shown in FIG. 9 for an air curtain apparatus can also be used to accelerate the dry and clean airflow and/or de-electrostatic ionized airflow sprayed by the conventional air curtain apparatus 100 or 200 or the air curtain apparatus 300 or 400 according to this present invention. As shown in FIG. 8, the structure of the airflow accelerator 40′ is similar to that of the airflow accelerator 40 shown in FIGS. 5A˜5B, except that the structure of the airflow accelerator 40′ further comprises a first side part 40D adjacent to the base part 40A, the connecting part 40B and the terminal part 40C. As shown in FIG. 9, the structure of the airflow accelerator 40″ is similar to that of the airflow accelerator 40 shown in FIGS. 5A˜5B, except that the structure of the airflow accelerator 40″ further comprises a first side part 40D and a second side part 40E adjacent to the base part 40A, the connecting part 40B and the terminal part 40C, wherein the first side part 40D and the second side part are opposite to each other.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

What is claimed is:

1. An air curtain apparatus for spraying a dry and clean airflow and/or a de-electrostatic ionized airflow toward a target, comprising:
an article with a first surface, a second surface, a third surface and a fourth surface adjacent to each other, and a first side surface and a second side surface on opposite end terminals of the article, wherein the first surface faces to the target, the first surface faces to the third surface, the second surface faces to the fourth surface, and the first side surface is adjacent to edges of the first surface, the second surface, the third surface and the fourth surface, and the second side surface is adjacent to another edges of the first surface, the second surface, the third surface and the fourth surface;
an air inlet, formed on the first side surface or the second side surface of the article;
a plurality of air-spraying heads formed on the first surface of the article; and
an accelerator, comprising:
a first conductive thin film, floatingly formed on the second surface adjacent to the first surface, wherein a first distance d1 that the first conductive thin film protruding out of the first surface is greater than a second distance d2 that the air-spraying heads protruding out of the first surface; and
a second conductive thin film, floatingly formed on the fourth surface adjacent to the first surface, wherein a first distance d1 that the second conductive thin film protruding out of the first surface is greater than a second distance d2 that the air-spraying heads protruding out of the first surface;
wherein, the first conductive thin film and the second conductive thin film protruding out of the first surface form a funnel structure owing to the gravity, which contributes to the dry and clean airflow and/or the de-electrostatic ionized airflow sprayed by the air-spraying heads be accelerated by the funnel structure and flowed vertically toward to the target.

2. The air curtain apparatus as claimed in claim 1, wherein the first conductive thin film and the second conductive thin film are flexible conductive plastic thin films or flexible metallic thin films.

3. The air curtain apparatus as claimed in claim 1, wherein the flexible conductive plastic thin films are made of polyimide.

4. The air curtain apparatus as claimed in claim 1, wherein the flexible metallic thin films are made of aluminum foil, tin foil or copper foil.

5. An air curtain apparatus for spraying a dry and clean airflow and/or a de-electrostatic ionized airflow toward a target, comprising:
an article with a first surface, a second surface, a third surface and a fourth surface adjacent to each other, and a first side surface and a second side surface on opposite end terminals of the article, wherein the first surface faces to the target, the first surface faces to the third surface, the second surface faces to the fourth surface, and the first side surface is adjacent to edges of the first surface, the second surface, the third surface and the fourth surface, and the second side surface is adjacent to another edges of the first surface, the second surface, the third surface and the fourth surface;
an air inlet, formed on the first side surface or the second side surface of the article;
an air-spraying slit formed on the first surface of the article; and
an accelerator, comprising:
a first conductive thin film, floatingly formed on the second surface adjacent to the first surface, wherein a first distance d1 that the first conductive thin film protruding out of the first surface is greater than a second distance d2 that the air-spraying slit protruding out of the first surface; and
a second conductive thin film, floatingly formed on the fourth surface adjacent to the first surface, wherein a first distance d1 that the second conductive thin film protruding out of the first surface is greater than a second distance d2 that the air-spraying slit protruding out of the first surface;
wherein, the first conductive thin film and the second conductive thin film protruding out of the first surface form a funnel structure owing to the gravity, which contributes to the dry and clean airflow and/or the de-electrostatic ionized airflow sprayed by the air-spraying slit be accelerated by the funnel structure and flowed vertically toward to the target.

6. The air curtain apparatus as claimed in claim 5, wherein the first conductive thin film and the second conductive thin film are flexible conductive plastic thin films or flexible metallic thin films.

7. The air curtain apparatus as claimed in claim 5, wherein the flexible conductive plastic thin films are made of polyimide.

8. The air curtain apparatus as claimed in claim 5, wherein the flexible metallic thin films are made of aluminum foil, tin foil or copper foil.

9. An airflow accelerator for an air curtain apparatus, comprising:
a base part, upwardly extending along with a first direction D1;
a terminal part; and
a connecting part for connecting the base part and the terminal part, extending along with a second direction D2, and an acute angle a is formed between the first direction D1 and the second direction D2;
wherein when the airflow accelerator for an air curtain apparatus is placed adjacent to a semiconductor equipment or a semiconductor processing room, a first gap g1 between the terminal part of the airflow accelerator for an air curtain apparatus and the semiconductor equipment or the semiconductor processing room is greater than a second gap g2 between the base part of the airflow accelerator for an air curtain apparatus and the semiconductor equipment or the semiconductor processing room, and an airflow with a first velocity of V1 sprayed by the air curtain apparatus will be accelerated by the airflow accelerator to generate an airflow with a second velocity of V2 when passing from the first gap g1 between the terminal part of the airflow accelerator for an air curtain apparatus and the semiconductor equipment or the semiconductor processing room 50 through the second gap g2 between the terminal part of the airflow accelerator for an air curtain apparatus and the semiconductor equipment or the semiconductor processing room.

10. The airflow accelerator for an air curtain apparatus as claimed in claim 9, wherein the airflow accelerator is made of a conductive plastic material or a metallic material.

11. The airflow accelerator for an air curtain apparatus as claimed in claim 10, wherein the conductive plastic material is polyimide.

12. The airflow accelerator for an air curtain apparatus as claimed in claim 10, wherein the metallic material is aluminum, tin or copper.

13. The airflow accelerator for an air curtain apparatus as claimed in claim 9, further comprising a first side part adjacent to the base part, the connecting part and the terminal part.

14. The airflow accelerator for an air curtain apparatus as claimed in claim 13, further comprising a second side part adjacent to the base part, the connecting part and the terminal part, wherein the first side part and the second side part are opposite to each other.
